(19) United States
(12) Patent Application Publication
(10) Pub. No.: US 2024/0326717 A1
(43) Pub. Date: Oct. 3, 2024

(54) SENSOR MODULE FOR BEING DISPOSED ON A MOTOR VEHICLE

(71) Applicant: Webasto SE, Stockdorf (DE)

(72) Inventor: Nikolaus LINNER, Stockdorf (DE)

(21) Appl. No.: 18/619,450

(22) Filed: Mar. 28, 2024

(30) Foreign Application Priority Data
Apr. 3, 2023 (DE) 10 2023 108 471.2

(51) Int. Cl. B60R 11/04; B60R 11/00; G01S 7/02; G01S 13/931; H04N 23/51; H04N 23/52

(52) U.S. Cl. CPC B60R 11/04; G01S 7/028; G01S 13/931; H04N 23/51; H04N 23/52; B60R 2011/004; B60R 2011/0043; G01S 2013/9323; G01S 2013/9324; G01S 2013/93273

(57) ABSTRACT

A sensor module for being disposed on a motor vehicle has at least one environment sensor configured to send/and or receive electromagnetic signals for detecting a vehicle environment and a sensor housing at least partially surrounding and/or enclosing and/or encasing the at least one environment sensor. The sensor housing has at least one housing portion made of a metallic material, the housing portion being in heat-transferring connection with the at least one environment sensor, allowing exhaust heat emitted by the environment sensor and/or introduced into the sensor module from outside to be discharged via the at least one housing portion.

### CROSS-REFERENCE TO RELATED APPLICATION

This application claims the benefit of German Patent Application No. 10 2023 108 471.2 filed Apr. 3, 2023, which is incorporated herein by reference in its entirety.

### TECHNICAL FIELD

The invention relates to a sensor module for being disposed on a motor vehicle, the sensor module having at least one environment sensor configured to send/and or receive electromagnetic signals for detecting a vehicle environment and a sensor housing at least partially surrounding and/or enclosing and/or encasing the at least one environment sensor.

### BACKGROUND

Generic sensor modules are used in roof modules, for example. Such roof modules are prefabricated as separate functional modules and can be delivered to the assembly line as a structural unit when the vehicle is assembled. The roof module at least partially forms a roof skin of the vehicle roof, the roof skin preventing moisture or air flow from entering the vehicle interior. The roof skin is formed by one or multiple panel components, which can be made of a stable material, such as painted metal or painted or died-through plastic. The roof module can be part of a fixed vehicle roof or part of an openable roof assembly.

Furthermore, developments in vehicle construction are increasingly focusing on autonomous or semi-autonomous motor vehicles. In order to enable the vehicle control system to control the motor vehicle autonomously or semi-autonomously, a large number of environment sensors (e.g., lidar sensors, radar sensors, (multi-) cameras, etc. including other (electrical) components) are used, which are integrated in sensor modules and/or a roof module, for example. The environment sensors detect the environment surrounding the motor vehicle and determine, for example, a traffic situation from the detected environmental data. Roof modules which have a plurality of environment sensors and/or sensor modules are also known as roof sensor modules (RSM).

The known environment sensors send and receive electromagnetic signals, such as laser beams or radar beams, allowing a data model of the vehicle environment to be generated by signal evaluation and used for vehicle control. In order to protect the environment sensors from harmful environmental influences, such as moisture and air currents, the environment sensors are installed in a sensor housing or integrated in the roof module, for example. Either way the environment sensors are mounted, they protrude above the top of the roof skin formed by the roof module to provide the environment sensor in question with an all-round view.

For the best possible and reliable operation, safety and availability of the autonomous or semi-autonomous driving mode, the environment sensors and the other (electrical) components must be available as continuously as possible. An existing problem that can cause the (temporary) failure of an environment sensor is, for example, the build-up of heat, which can cause the environment sensor to overheat and consequently fail. This type of heat build-up can be caused not only by the environment sensor's own heat generated during operation but also by ambient heat introduced.

The use of cooling devices is known to avoid these heat-related problems. Heat is dissipated, for example, via air ducts and/or the use of fans. The cooling air for cooling the at least one environment sensor can come from the interior or from outside. The known cooling devices are often elaborately designed and have a plurality of components, such as heat pipes and/or heat exchangers and/or other heat-conducting elements. This makes implementing such a cooling device structurally complex. In addition, subsequent maintenance is often time-consuming and complex. Furthermore, an installation space required for the cooling devices is relatively large. If the cooling air is supplied from outside, water management is also required in order to drain any rainwater from the cooling device.

### SUMMARY

One object of the invention is to provide an improved sensor module.

This object is attained by a sensor module for being disposed on a motor vehicle, the sensor module having at least one environment sensor configured to send and/or receive electromagnetic signals for detecting a vehicle environment and a sensor housing at least partially surrounding and/or enclosing and/or encasing the at least one environment sensor, characterized in that the sensor housing has at least one housing portion made of a metallic material, the housing portion being in heat-transferring connection with the at least one environment sensor, allowing exhaust heat emitted by the environment sensor and/or introduced into the sensor module from outside to be discharged via the at least one housing portion.

Advantageous embodiments of the invention can include the following features.

The at least one housing portion has at least one side wall made of a metallic material, the at least one side wall being in, in particular flat and/or direct, heat-transferring contact with the at least one environment sensor.

The at least one housing portion has multiple cooling fins and/or is provided with multiple cooling fins.

The multiple cooling fins extend essentially parallel to a direction of travel or longitudinally extend at an acute angle relative to the direction of travel, allowing headwind to flow along the cooling fins.

The at least one housing portion fully surrounds and/or encloses the at least one environment sensor, in particular in a flush manner.

The sensor housing has at least one cover externally covering and/or canopying and/or capping the at least one environment sensor.

The at least one cover has an infrared reflection layer configured to reduce the heat introduced into the sensor module from outside.

The at least one cover comprises plastic, preferably polycarbonate.

The at least one environment sensor is configured to be moved between a retracted position and a deployed position, heat being discharged via the at least one housing portion in the deployed position.

The at least one environment sensor comprises a lidar sensor and/or a radar sensor and/or a camera sensor and/or a multi-camera sensor and/or an ultrasonic sensor.

A roof module, for forming a vehicle roof on a motor vehicle, can having a panel component, which at least partly forms a roof skin of the vehicle roof, the roof skin serving as an outer sealing surface, and at least one sensor module according to the invention, the sensor module being disposed on the panel component and/or comprised by the panel component (12).

A motor vehicle can comprise at least one sensor module according to the invention and/or a roof module according to the invention, the roof module being disposed on a vehicle body of the motor vehicle as a structural unit.

Any and all combinations of at least two features disclosed in the description, the claims, and/or the figures fall within the scope of the invention. Naturally, the explanations given in connection with the sensor module equivalently relate to the roof module according to the invention and/or the motor vehicle according to the invention without being mentioned separately in its context. In particular, linguistically common rephrasing and/or an analogous replacement of respective terms within the scope of common linguistic practice, in particular the use of synonyms backed by the generally recognized linguistic literature, are of course comprised by the content of the disclosure at hand without every variation having to be expressly mentioned.

In its intended use, the sensor module according to the invention is configured to be disposed on a motor vehicle. The sensor module has at least one environment sensor configured to send and/or receive electromagnetic signals, in particular through a see-through area of the sensor module, in order to detect a vehicle environment. The sensor module comprises a sensor housing at least partially surrounding and/or enclosing and/or encasing the at least one environment sensor. The sensor housing can also comprise only one housing part. The sensor housing may at least partially comprise the preferred see-through area. The sensor housing has at least one housing portion made of a metallic material and/or of a highly thermally conductive material, in particular a carbonaceous material, such as graphene and/or carbon and/or graphite. As an alternative or in addition to a metallic material, the housing can, for example, comprise a carbonaceous material. The housing portion is in heat-transferring connection with the at least one environment sensor, allowing exhaust heat emitted and/or generated by the environment sensor and/or heat introduced into the sensor module from outside, in particular by solar radiation, to be discharged via the at least one housing portion. Components of the environment sensor that emit and/or generate waste heat are preferably in direct contact with the at least one housing portion.

The sensor module according to the invention is very simple and inexpensive to produce. The sensor housing, in particular the at least one housing portion, additionally forms a cooling device, in particular integrally with the sensor module. Furthermore, no water management is required according to the invention since no cooling air which must be introduced and/or fed into a cooling device from outside the motor vehicle is required. The ambient air is preferably only in direct contact with the at least one housing portion and enables convective heat dissipation from the sensor module. In particular when the motor vehicle moves, the ambient air passes over the at least one housing portion, thereby increasing the convective heat dissipation. The metallic material can preferably comprise copper and/or aluminum and/or iron and/or steel. Alloys and/or metallic additives are also possible.

In a preferred embodiment, the at least one housing portion has at least one side wall made of a metallic material, the at least one side wall being in, in particular flat and/or direct, heat-transferring contact with the at least one environment sensor, in particular with components of the environment sensor producing waste heat. The at least one side wall preferably extends transversely to a surface of the motor vehicle on which the sensor module is disposed. For example, the side wall preferably extends transversely to a roof skin of the vehicle roof and/or of a roof module.

In a preferred embodiment, the at least one housing portion has multiple cooling fins and/or is provided with multiple cooling fins. The multiple cooling fins preferably run essentially parallel to the direction of travel and/or longitudinally extend at an acute angle relative to the direction of travel, allowing headwind to flow along the cooling fins. Various types of cooling fins may be preferred. For example, they can be straight cooling fins that extend straight, in particular along a direction of travel of the motor vehicle, and protrude from the housing portion. Corrugated cooling fins may be used. These cooling fins have an undulating surface that provides a larger surface area for heat dissipation. Lamella cooling fins may be used. These cooling fins comprise many thin, flat plates that are stacked and connected to each other. Pin fin cooling fins may be used. These cooling fins comprise many small pins that protrude from the housing portion. They provide a very high surface area for heat dissipation. The cooling fins can be disposed on the at least one housing portion as additional components. The cooling fins can also be integral with the at least one housing portion.

In a preferred embodiment, the at least one housing portion surrounds and/or encloses the at least one environment sensor completely and in particular in a flush manner. This allows heat to be dissipated from the environment sensor preferably via all housing surfaces. Ideally, the sensor should therefore be completely enclosed by the at least one housing portion or the sensor housing.

In a preferred embodiment, the sensor housing has at least one cover externally covering and/or canopying and/or capping the at least one environment sensor. The cover preferably forms a lid part and/or a lid element of the sensor module. The cover covers the environment sensor when the sensor module is rigidly attached to the motor vehicle. In the closed state of a retractable and deployable environment sensor, the cover preferably covers an opening in which the environment sensor is disposed. The cover can be disposed on the sensor housing as an additional component. The cover can also be integral with the housing.

In a preferred embodiment, the at least one cover has an infrared reflection layer which can reduce the heat introduced into the sensor module from the outside. This can provide protection against solar radiation. The infrared reflection layer can be laminated onto the cover as a film and/or integrated into a multilayer structure of the cover. Alternatively or additionally, the infrared reflection layer can be applied to the cover as a coating. Alternatively or additionally, the infrared reflection layer can be applied as a coating to a backing film disposed on at least part of the cover and/or integrated in the cover.

In a preferred embodiment, the at least one cover comprises plastic, preferably polycarbonate (PC). The upper side of the sensor housing or the cover can be made of a different material, e.g., PC, than the at least one housing portion. The cover can provide a high-quality surface of the sensor housing, in particular in visual terms. Depending on the material selected, the cover can be produced cost-effectively in multiple variants.

In a preferred embodiment, the at least one environment sensor can be moved between a retracted position and a deployed position. In the deployed position, heat is discharged via the at least one housing portion. In particular, heat is discharged by the headwind and/or ambient wind flowing around across at least one housing portion. This results in convective heat dissipation. The at least one environment sensor can basically be moved in any manner. For example, the sensor module can comprise an adjustment device with at least one drive which can move the at least one environment sensor between the retracted position and the at least one deployed position.

In a preferred embodiment, the at least one environment sensor comprises a lidar sensor and/or a radar sensor and/or a camera sensor and/or a multi-camera sensor and/or an ultrasonic sensor. Other sensors and/or other electrical and/or electronic and/or electromagnetic components are also conceivable.

The invention also proposes a roof module for forming a vehicle roof on a motor vehicle. The roof module has a panel component which at least partially forms a roof skin of the vehicle roof, the roof skin serving as an outer sealing surface, and at least one sensor module according to any embodiment of the invention. The sensor module is disposed on the panel component and/or is comprised by the panel component. For example, the sensor module may be disposed in an opening of the panel component and may be moved between a retracted position and a deployed position relative to the panel component. The optional cover of the sensor housing preferably closes flush with the surrounding panel component when the sensor module is in the retracted position. The roof module according to the invention can form a structural unit in which devices for autonomous or semi-autonomous driving supported by driver assistance systems are integrated and which can be mounted on top of a vehicle body as a structural unit by a vehicle manufacturer. Furthermore, the roof module according to the invention can be designed as a purely fixed roof or as a roof including a roof opening system. In addition, the roof module can be designed for use in a passenger car or in a commercial vehicle. The roof module can preferably be provided as a structural unit in the form of a roof sensor module (RSM) in which the environment sensors are provided in order to be inserted into a roof frame of a vehicle body as a deliverable structural unit.

The invention also proposes a motor vehicle. The motor vehicle has at least one sensor module according to any embodiment of the invention and/or a roof module disposed on a vehicle body of the motor vehicle as a structural unit.

### BRIEF DESCRIPTION OF DRAWINGS

Embodiments of the invention are schematically illustrated in the drawing and are explained below by way of example.

FIG. 1 is a schematic view of an embodiment example of a motor vehicle with a roof module and with a sensor module according to the invention;

FIG. 2 is a schematic view of an embodiment example of a sensor module according to the invention; and

FIG. 3 is a sectional view of the sensor module shown in FIG. 2.

### DETAILED DESCRIPTION

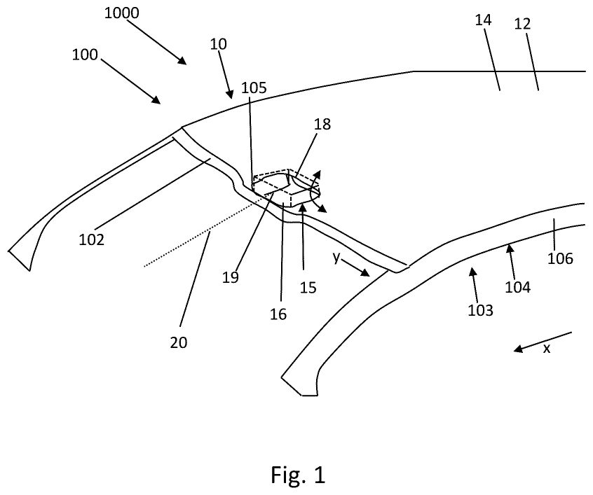

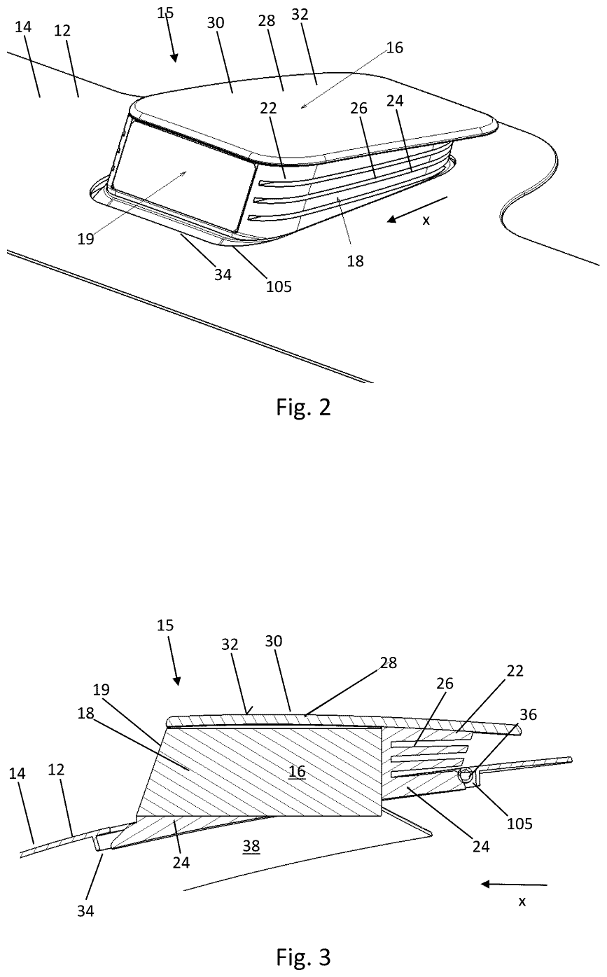

FIG. 1 shows a vehicle roof 100 of a vehicle 1000 (not shown in its entirety). In the case at hand, the vehicle roof 100 is a roof module 10. The roof module 10 comprises a panel component 12 for forming a roof skin 14 of the vehicle roof 100, the roof skin 14 serving as an outer sealing surface. The roof module 10 optionally comprises a roof module frame on which the panel component 12 is disposed or to which the panel component 12 is captively attached, for example glued. The roof module 10 is disposed on a roof frame structure 104 of the vehicle 1000, in the case at hand mounted on top of the latter, as a structural unit. The roof frame structure 104 comprises a front-side and a rear-side transverse body rail 102, only the front-side transverse body rail 102 being visible. Furthermore, the roof frame structure 104 comprises at least two longitudinal body rails 106. In the case at hand, the roof body frame 104 is part of a vehicle body 103 of the motor vehicle 1000.

In the case at hand, the roof module 10 comprises at least one sensor module 15 having at least one retractable and deployable environment sensor 16. The sensor module 15 is disposed in an opening 105 of the panel component 12 in such a manner that the at least one environment sensor 16 can be moved between a retracted position and a deployed position. The movability is schematically shown with a double arrow in FIG. 1. In the case at hand, the sensor module 15 is disposed in a front-side, central area behind the front-side transverse body rail 102 as viewed in a longitudinal vehicle direction x, the front-side transverse body rail 102 forming a header. The longitudinal vehicle direction x is orthogonal to a vehicle width direction y.

The sensor module 15 comprises a sensor housing 18. The sensor housing 18 has a see-through area 19, which is directed toward the front in the case at hand. The at least one environment sensor 16 is configured to send and/or receive electromagnetic signals through the see-through area 19 in order to detect a vehicle environment. The environment sensor 16 detects a vehicle environment in a field of view around an optical axis 20. The sensor module 15 can comprise multiple, in particular different, environment sensors 16. The at least one environment sensor 16 preferably comprises a lidar sensor and/or a radar sensor and/or a camera sensor and/or a multi-camera sensor and/or an ultrasonic sensor and/or a light source.

The sensor housing 18 comprises at least one housing portion 22 made of a metallic material. The housing portion 22 is in heat-transferring connection with the at least one environment sensor 16, allowing exhaust heat emitted by the environment sensor 16 and/or introduced into the sensor module 15 from outside to be discharged via the at least one housing portion 22. The housing portion 22 is made of aluminum, for example.

The housing portion 22 has at least one side wall 24 made of a metallic material, the at least one side wall 24 being in flat and/or direct heat-transmitting contact with the at least one environment sensor 16. A heat-conducting paste for optimized heat conduction can also be provided between the side wall 24 and the environment sensor 16, for example.

The at least one housing portion 22 or the at least one side wall 24 has multiple cooling fins 26. The cooling fins 26 are formed integrally with the housing portion 22 in the case at hand. The cooling fins 26 preferably at least partially extend essentially along the longitudinal vehicle direction x, which corresponds to a direction of travel of the motor vehicle 1000 in the case at hand. The multiple cooling fins 26 are essentially aligned parallel to the direction of travel, or longitudinally extend at an acute angle relative to the direction of travel, allowing headwind to flow along the cooling fins 26.

The sensor housing 18 has at least one cover 28 which externally covers and/or canopies and/or caps the at least one environment sensor 16. In the case at hand, the cover 28 is made of polycarbonate and is placed on top of the at least one housing portion 22. The at least one housing portion 22 surrounds and/or encloses the at least one environment sensor 16 completely and in particular in a flush manner.

The at least one cover 28 has an infrared reflection layer 30 which reduces the heat introduced into the sensor module 15 from the outside. The infrared reflection layer 30 is applied to an outer surface 32 of the cover 28 as a coating in the case at hand.

A sealing assembly 36 is provided in an edge area 34 of the opening 105, the sealing assembly 36 preventing water and/or moisture from entering an interior 38 of the roof module 10 at least in the retracted state and in the deployed state of the at least one environment sensor 16. In the case at hand, the sealing assembly 36 completely surrounds the edge area 34 of the opening 105.

### REFERENCE SIGNS

10 roof module
12 panel component
14 roof skin
15 sensor module
16 environment sensor
18 sensor housing
19 see-through area
20 optical axis
22 housing portion
24 side wall
26 cooling fins
28 cover
30 infrared reflection layer
32 surface
34 edge area
36 sealing assembly
38 interior
100 vehicle roof
102 transverse body rail
103 vehicle body
104 roof frame structure
105 opening
106 longitudinal body rail
1000 motor vehicle
x longitudinal vehicle direction
y vehicle width direction

1. A sensor module for being disposed on a motor vehicle, the sensor module having at least one environment sensor configured to send and/or receive electromagnetic signals for detecting a vehicle environment and a sensor housing at least partially surrounding and/or enclosing and/or encasing the at least one environment sensor, wherein the sensor housing has at least one housing portion made of a metallic material, the housing portion being in heat-transferring connection with the at least one environment sensor, allowing exhaust heat emitted by the environment sensor and/or introduced into the sensor module from outside to be discharged via the at least one housing portion.

2. The sensor module according to claim 1, wherein the at least one housing portion has at least one side wall made of a metallic material, the at least one side wall being in heat-transferring contact with the at least one environment sensor.

3. The sensor module according to claim 1, wherein the at least one housing portion has multiple cooling fins and/or is provided with multiple cooling fins.

4. The sensor module according to claim 3, wherein the multiple cooling fins extend essentially parallel to a direction of travel or longitudinally extend at an acute angle relative to the direction of travel, allowing headwind to flow along the cooling fins.

5. The sensor module according to claim 1, wherein the at least one housing portion fully surrounds and/or encloses the at least one environment sensor.

6. The sensor module according to claim 1, wherein the sensor housing has at least one cover externally covering and/or canopying and/or capping the at least one environment sensor.

7. The sensor module according to claim 6, wherein the at least one cover has an infrared reflection layer configured to reduce the heat introduced into the sensor module from outside.

8. The sensor module according to claim 6, wherein the at least one cover comprises plastic, preferably polycarbonate.

9. The sensor module according to claim 1, wherein the at least one environment sensor is configured to be moved between a retracted position and a deployed position, heat being discharged via the at least one housing portion in the deployed position.

10. The sensor module according to claim 1, wherein the at least one environment sensor comprises a lidar sensor and/or a radar sensor and/or a camera sensor and/or a multi-camera sensor and/or an ultrasonic sensor.

11. A roof module for forming a vehicle roof on a motor vehicle, the roof module having a panel component, which at least partly forms a roof skin of the vehicle roof, the roof skin serving as an outer sealing surface, and at least one sensor module according to claim 1, the sensor module being disposed on the panel component and/or comprised by the panel component.

12. A motor vehicle comprising the roof module according to claim 11, the roof module being disposed on a vehicle body of the motor vehicle as a structural unit.

13. The sensor module according to claim 2, wherein the at least one side wall is in flat and/or direct heat-transferring contact with the at least one environment sensor.

14. The sensor module according to claim 5, wherein the at least one housing portion fully surrounds and/or encloses the at least one environment sensor in a flush manner.
